(19) United States
(12) Patent Application Publication
(10) Pub. No.: US 2025/0384903 A1
(43) Pub. Date: Dec. 18, 2025

(54) DISTRIBUTED STRING DRIVERS UNDER AN ARRAY

(71) Applicant: Micron Technology, Inc., Boise, ID (US)

(72) Inventors: Yoshiaki Fukuzumi, Yokohama (JP); Matthew J. King, Boise, ID (US)

(21) Appl. No.: 19/235,228

(22) Filed: Jun. 11, 2025

Related U.S. Application Data
(60) Provisional application No. 63/660,921, filed on Jun. 17, 2024.

(51) Int. Cl. G11C 5/06; G11C 16/04; H10B 43/35; H10D 64/66

(52) U.S. Cl. CPC G11C 5/063; G11C 16/0483; H10B 43/35; H10D 64/665

(57) ABSTRACT

Methods, systems, and manufacturing processes for distributed string drivers under an array are described. A memory architecture a subarray layer positioned above a substrate including a quantity of string driver regions. Each string driver region is separated from other string driver regions by a page buffer, and includes a quantity of string drivers and one or more contacts. The memory architecture includes one or more array layers positioned above the first layer and including a quantity of contact regions and a quantity of array regions. Each contact region is positioned above a respective string driver region, and is positioned between a respective pair of contact regions. Each array region includes a quantity of bit lines positioned above the string driver regions and coupled with the page buffer. Each array region also includes a quantity of word lines each coupled with a respective string driver via a contact region.

### CROSS REFERENCE

The present application for patent claims priority to U.S. Patent Application No. 63/660,921 by Fukuzumi et al., entitled “DISTRIBUTED STRING DRIVERS UNDER AN ARRAY,” filed Jun. 17, 2024, which is assigned to the assignee hereof, and which is expressly incorporated by reference in its entirety herein.

### TECHNICAL FIELD

The following relates to one or more systems for memory, including distributed string drivers under an array.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports distributed string drivers under an array in accordance with examples as disclosed herein.

FIG. 2 shows an example of a memory architecture that supports distributed string drivers under an array in accordance with examples as disclosed herein.

FIGS. 3A, 3B, 3C, 3D, 3E, 3F, 3G, 3H, 3I, 3J, 3K, 3L, 3M, and 3N show examples of processing steps that support distributed string drivers under an array in accordance with examples as disclosed herein.

FIG. 4A, 4B, 4C, 4D, 4E, 4F, 4G, 4H, 4I, and 4J show examples of processing steps that support distributed string drivers under an array in accordance with examples as disclosed herein.

FIG. 5 shows a flowchart illustrating a method or methods that support distributed string drivers under an array in accordance with examples as disclosed herein.

### DETAILED DESCRIPTION

In some memory systems, one or more memory devices (e.g., dies), may be scaled (e.g., decreased in size) to support implementing a relatively greater quantity of memory devices in the memory system, or to support a relatively smaller memory system overall (e.g., implementing a same or smaller quantity of memory devices in the memory system). In some such memory systems, scaling the one or more memory devices may include scaling a memory architecture of one or more arrays (memory arrays) implemented by the one or more memory devices. Additionally, or alternatively, scaling the memory architecture may include reducing an area associated with one or more data paths of the memory architecture. For example, scaling the memory architecture may include scaling a routing of access lines, which may cause connections between word lines (e.g., access lines associated with accessing memory cells of the memory architecture) and string drivers (e.g., drivers associated with activating the word lines) to exhibit electrical distortions due to the decreased size and/or spacing. In some such examples, the memory architecture may implement the string drivers in one or more concentrated regions beneath the word lines with routing from the string driver region to a single word line contact area (e.g., staircase), thereby causing relatively increased word line contact complexity, and exacerbating electrical distortions caused by the scaling. That is, as a quantity of word lines increases, shorting may occur in the memory architecture in some examples due to a decreased space for implementing the word lines and string drivers (e.g., a decreased space between adjacent word lines and adjacent string drivers). Further, in some cases, processes (e.g., manufacturing operations) to support scaling the memory architecture may be insufficient for preventing shorting, and may be relatively expensive and/or complex to implement, among other challenges.

In accordance with examples as described herein, a memory architecture may implement string drivers in multiple regions distributed across the memory architecture, which may support scaling the respective memory device, among other advantages. For example, the string drivers may be grouped in multiple regions distributed below word lines (e.g., below the cell array portion) of the memory architecture. Implementing the string drivers in groups distributed across the memory architecture may alleviate scaling issues by reducing word line contact complexity (e.g., due to reducing a quantity of word line contacts at a singular region to avoid routing congestion). Additionally, or alternatively, processes described herein to further support reduced memory array sizing may include forming word line contacts alongside pillars of the memory architecture. For example, cyclic isotropic etching processes may form word line contacts at target layers of the memory architecture without forming a staircase region. That is, the process for forming the memory architecture may consolidate one or more operations associated with manufacturing the memory architecture, which may be relatively cost effective and simple to implement (e.g., compared to previous processes), among other advantages.

In addition to applicability in memory systems described herein, techniques for distributed string drivers under an array may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may improve the security of electronic devices and systems by distributing components (e.g., string drivers, word line contacts) throughout a memory architecture, which may decrease shorting of the memory architecture, thereby improving connectivity and reliability for operating the memory architecture, among other benefits.

In addition to applicability in memory systems as described herein, techniques for distributed string drivers under an array may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by distributing components (e.g., string drivers, word line contacts) throughout a memory architecture, which may reduce manufacturing overhead and degradation of the memory architecture, thereby reducing electronic waste, among other benefits.

Features of the disclosure are illustrated and described in the context of systems and devices. Features of the disclosure are further illustrated and described in the context of processing steps and flowcharts.

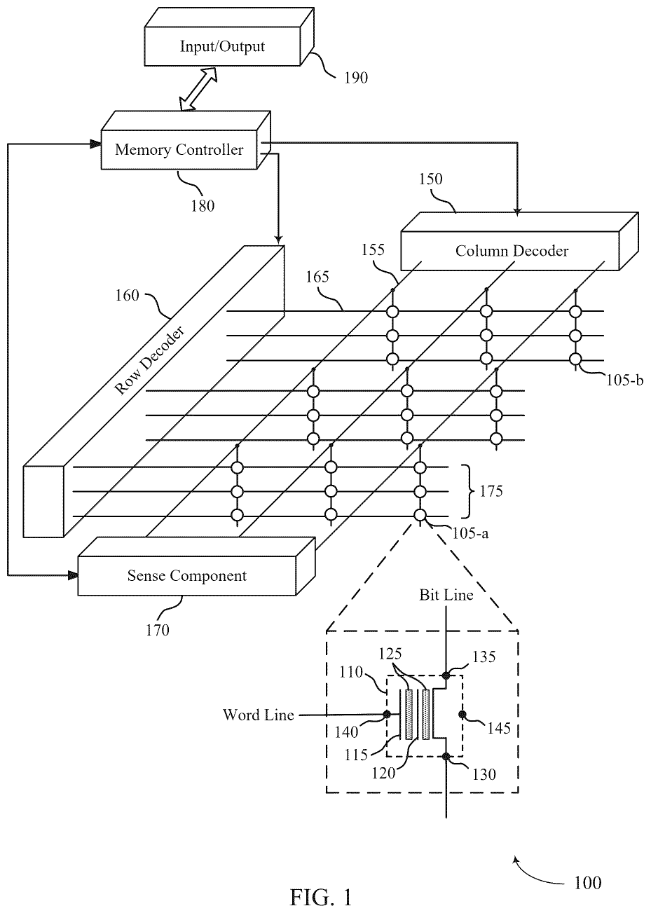

FIG. 1 shows an example of a memory device 100 that supports distributed string drivers under an array in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, charge-trap material, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on the current or potential of bit line 155 by applying seven or eight different read voltages to the control gate to define the eight threshold voltage values.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to bit line 155, the potential difference between the control node 140 and the bulk node 145 which is the channel of the transistor 110, by raising the potential of the bulk node by controlling the potential of bit line 155 depending on the data to be written, electron injection may be inhibited due to reduced electric field across cell film of the transistor 110. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as select lines and access lines.

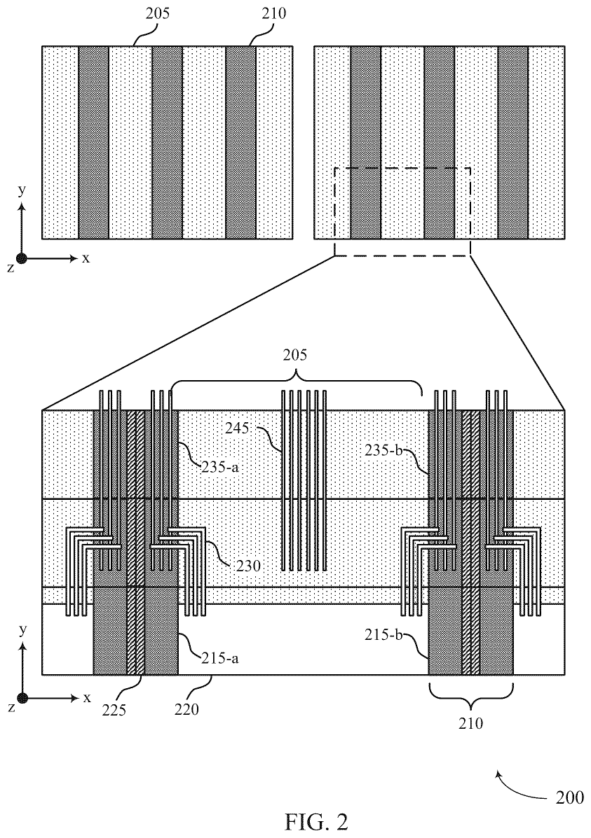

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 (e.g., with transistors coupled in series) may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In accordance with examples as described herein, a memory architecture may implement string drivers in multiple regions distributed underneath the memory architecture, which may support scaling the respective memory device 100. For example, the string drivers may be grouped in multiple regions distributed below word lines 165 (e.g., below the cell array portion) of the memory architecture. Implementing the string drivers in groups distributed across the memory architecture may alleviate scaling issues by reducing word line contact complexity (e.g., due to reducing a quantity of word line contacts at a singular region to avoid routing congestion). Processes to support implementing the string drivers in groups distributed below the memory architecture may include forming word line contacts alongside pillars of the memory architecture. For example, cyclic etching processes may form word line contacts at target layers of the memory architecture without forming a staircase region. That is, the process for forming the memory architecture may consolidate one or more operations associated with manufacturing the memory architecture, which may be relatively cost effective and simple to implement (e.g., compared to previous processes).

FIG. 2 shows an example of a memory architecture 200 that supports distributed string drivers under an array in accordance with examples as disclosed herein. The memory architecture 200 may be implemented within a memory device, which may be an example of a memory device 100, as described with reference to FIG. 1. Likewise, the memory architecture 200 may implement aspects or operations of the memory device 100, such as word lines, which may be examples of word lines 165, as described with reference to FIG. 1. For illustrative purposes, aspects of the memory architecture 200 may be described with reference to an x-direction, a y-direction, and a z-direction of the illustrated coordinate systems. For example, FIG. 2 illustrates the memory architecture 200 from a top view in an xy-plane, where the memory architecture 200 extends a distance in the z-direction into the page. Although the memory architecture 200 illustrates examples of relative dimensions and quantities of various features, aspects of the memory architecture 200 may be implemented with other relative dimensions or quantities of such features in accordance with examples as disclosed herein.

The memory architecture 200 may include array regions 205 and subarray regions 210 disposed above a substrate (e.g., not shown) along the z-direction. In some cases, the array regions 205 and CMOS wafers are processed separately, and bonded together by wafer-to-wafer bonding technology. The array regions 205 may be associated with a memory array of the memory device, and the subarray regions 210 may be associated with supporting circuitry for the memory array of the memory device. For example, the array regions 205 may include an array of memory cells and access lines for the memory cells, and the subarray regions 210 may include drivers, buffers, and other components (e.g., decoders) for supporting the array regions 205. In some implementations, the array regions 205 and the subarray regions 210 may each be associated with one or more layers of the memory architecture 200. For example, the array regions 205 may be associated with array layers, and the subarray regions 210 may be associated with subarray layers.

The subarray regions 210 may include string driver regions 215 extending from the substrate along the z-direction, and extending along the y-direction into the memory architecture 200. Each string driver region 215 may be separated relative to the x-direction, such that a string driver region 215-a may be separated from a string driver region 215-b. In some cases, the subarray regions 210 may include a page buffer 220 disposed above the substrate and between the string driver regions 215. For example, a portion of the page buffer 220 may extend between the string driver region 215-a and the string driver region 215-b relative to the x-direction, and may be adjacent to the string driver regions 215 along the y-direction. In some implementations, the page buffer 220 may be associated with sensing data from bit lines 245 of the array region 205 and temporarily storing data for read and program operations. In some such implementations, the page buffer 220 may be coupled with the bit lines 245 via contact lines 230. Each string driver region 215 may include one or more groups of string drivers, where each group of string drivers may include a quantity of string drivers. For example, each string driver region 215 may include two groups of string drivers, where each group of string drivers may include 128 string drivers, or some other quantity of string drivers. The string drivers may be associated with activating word lines (e.g., not illustrated for clarity) of the array regions 205. For example, each string driver may be configured to couple with one or more word lines and supply access signals to the one or more word lines.

In some examples, each string driver region 215 may include contacts 225 associated with coupling the string drivers of the string driver region 215 with a staircase region (e.g., not shown) of the memory architecture 200. In some implementations, each string driver region 215 may include one or more contacts 225 disposed between the groups of string drivers relative to the x-direction, such as two contacts 225 disposed between the two groups of string drivers. In some such implementations, the contacts 225 may extend from the substrate along the z-direction, and extend along the y-direction through the memory architecture 200.

The array regions 205 may include contact regions 235 extending from the subarray regions 210 along the z-direction, and extending along the y-direction into the memory architecture 200. Each contact region 235 may be separated relative to the x-direction, such that a contact region 235-a may be separated from a contact region 235-b. In some cases, the array regions 205 may include a portion disposed above the subarray regions 210 (e.g., above the page buffer 220) and between the contact regions 235. Each portion of the array regions 205 may include a cell array and supporting access lines. For example, the portion may extend between the contact region 235-a and the contact region 235-b relative to the x-direction, and may be adjacent to the contact regions 235 along the x-direction. In some examples, each contact region 235 may be associated with a respective string driver region 215, such that each contact region 235 may be coupled with a respective string driver region 215. For example, each contact region 235 may be positioned above a respective string driver region 215 along the z-direction.

In some cases, each contact region 235 may include the contacts 225 associated with coupling the contact regions 235 with the staircase region. That is, the contacts 225 in the array region 205 may extend from the subarray regions 210 through the array regions 205 in the contact regions 235. In some examples, the contacts 225 may include word line contacts, configured to couple the word lines with the string driver regions 215. In some implementations, each contact region 235 may include the contacts 225 disposed between the groups of string drivers relative to the x-direction, such as two contacts 225 disposed between the two groups of string drivers.

The array regions 205 may include access lines, such as the word lines and bit lines 245. The bit lines 245 may extend along the y-direction into the memory architecture 200 above the subarray regions 210 (e.g., above the string driver regions 215) along the z-direction. The word lines may extend along the x-direction in the array regions 205, and each word line may be coupled with a respective string driver via a respective contact region 235. For example, each word line may be coupled with a respective string driver via a respective contact 225. In some cases, the array regions 205 may include one or more conductive contacts that extends along the z-direction from the contacts 225 through the array regions 205. In some such cases, the one or more conductive contacts include conductive material that extends along the x-direction in a target layer of the array regions 205. In some cases, each conductive contact may be coupled with a respective word line at the target layer based on the conductive material extending in the x-direction in the target layer. In some cases, the target layer may include one or more memory cells coupled with the conductive contact via one or more word lines.

Distributing the string driver regions 215 throughout the memory architecture 200 may support simple word line contact connectivity, which may reduce electrical issues associated with operating the memory architecture 200. For example, positioning the string driver regions 215 in the subarray regions 210 below the array regions 205 may reduce complexity associated with coupling the word lines with the string drivers. Likewise, positioning the string driver regions 215 throughout the memory architecture may support a greater quantity or a smaller size of the string driver regions 215. Thus, implementing the memory architecture 200 in a memory device may support scaling the memory device with reduced electrical disadvantages.

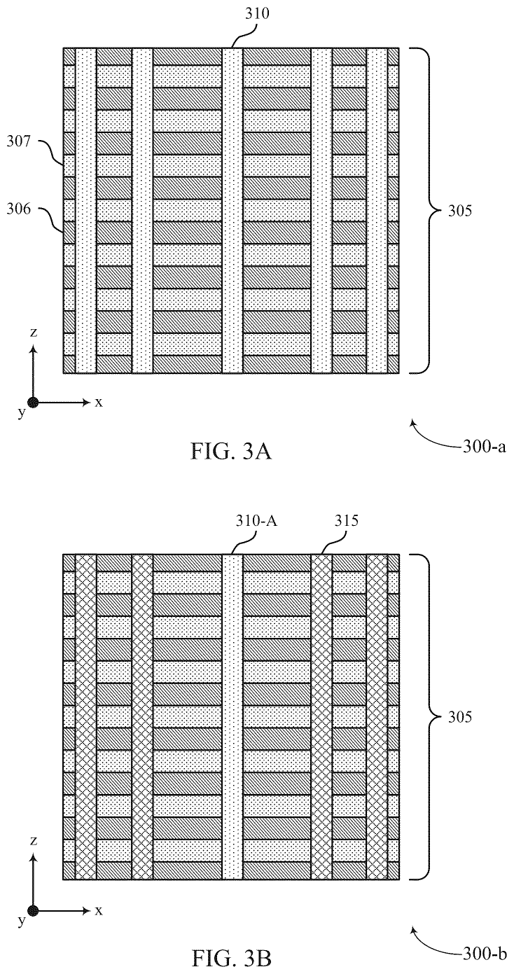

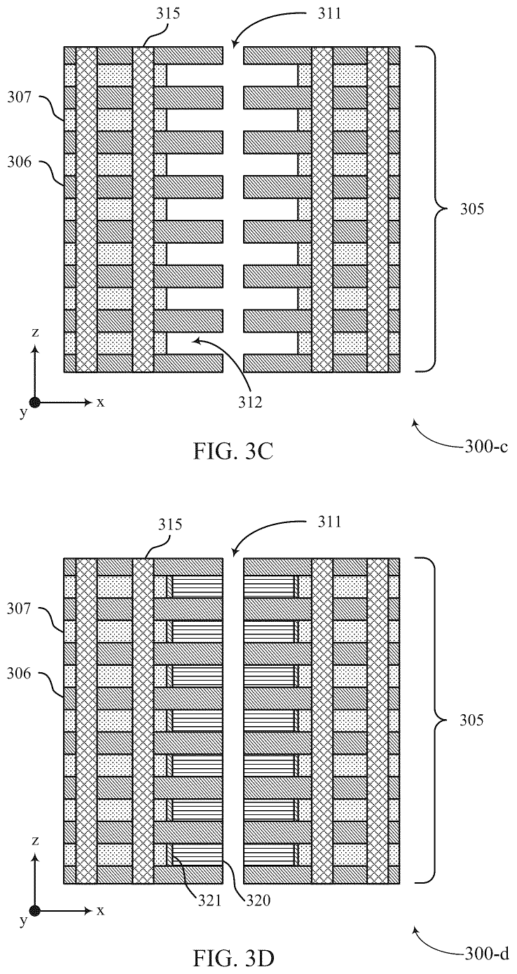

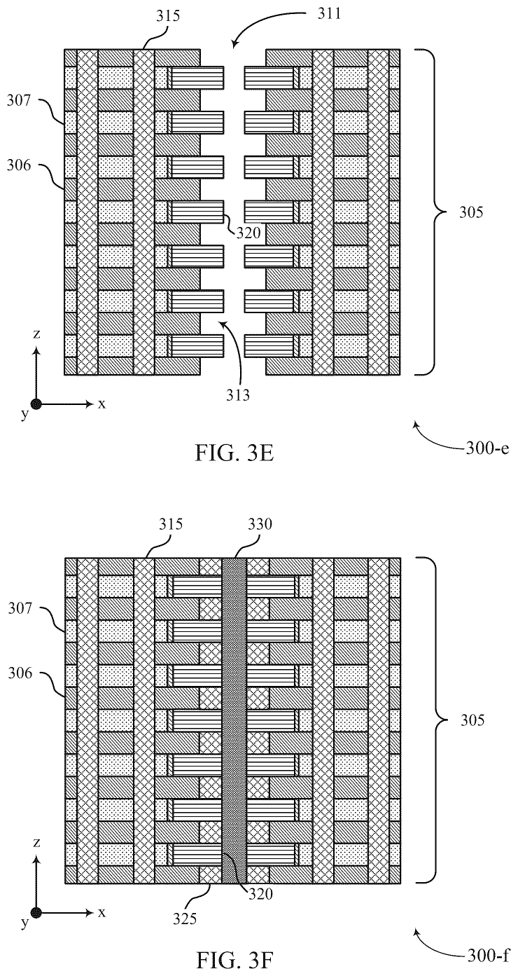

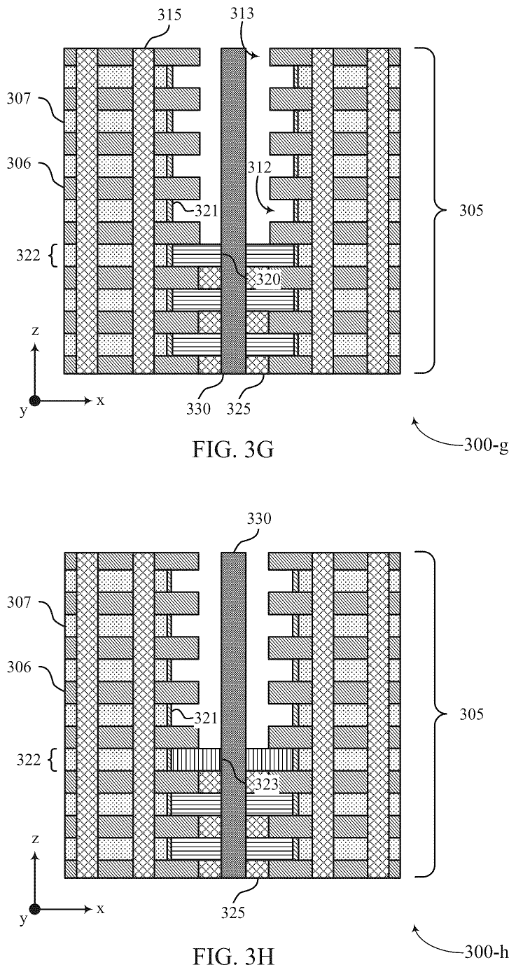

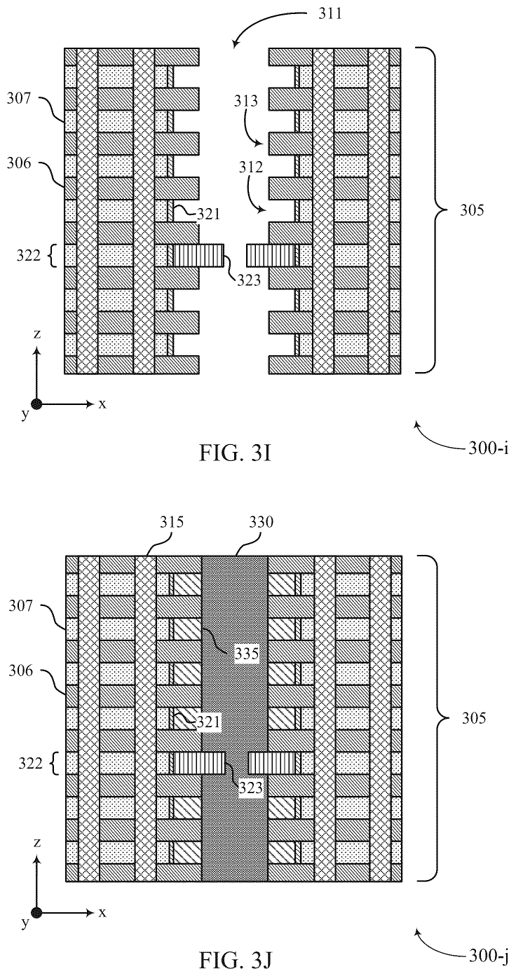

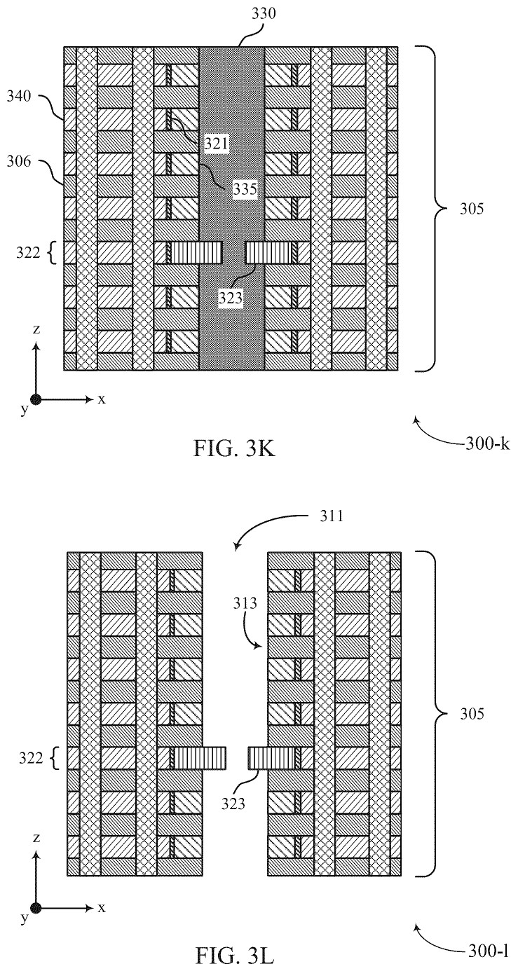

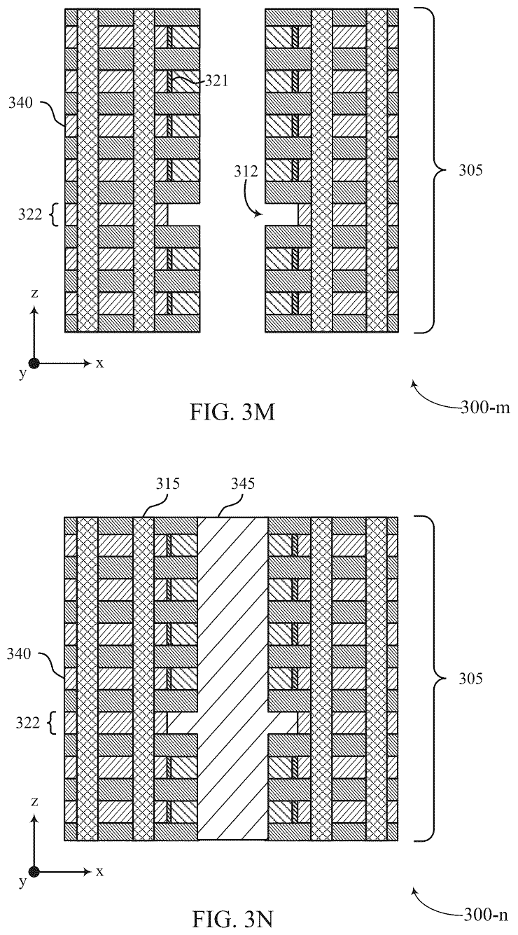

FIGS. 3A through 3N show examples of processing steps 300 that support distributed string drivers under an array in accordance with examples as disclosed herein. FIGS. 3A through 3N show various cross-sectional views of a memory architecture, which may be an example of a memory architecture 200, as described with reference to FIG. 2. The processing steps 300 may illustrate aspects of manufacturing operations for fabricating aspects of memory architecture, which may be implemented in a memory device or a memory array, such as a memory device 100, as described with reference to FIG. 1. The processing steps 300 may illustrate operations associated with implementing string drivers in groups distributed below the memory architecture by forming word line contacts alongside pillars of the memory architecture. For example, cyclic isotropic etching processes may form word line contacts at target layers of the memory architecture without forming a staircase region. That is, the process for forming the memory architecture described herein may consolidate one or more operations associated with manufacturing the memory architecture, which may be relatively cost effective and simple to implement (e.g., compared to previous processes). In addition, holes for word line contacts may be formed simultaneously with cell pillars which typically have a relatively small diameter and a relatively steep taper angle. As a result, the size of the word line contacts may be minimized to effectively reduce word line contact area.

For illustrative purposes, aspects of the memory architecture may be described with reference to an x-direction, a y-direction, and a z-direction of the illustrated coordinate systems. For example, processing steps 300-a, 300-b, 300-c, 300-d, 300-c, 300-f, 300-g, 300-h, 300-i, 300-j, 300-k, 300-l, 300-m, and 300-n illustrate the memory architecture from cross-sectional views in an xz-plane, where the memory architecture extends a distance along the y-direction into the page. Although the processing steps 300 illustrate examples of relative dimensions and quantities of various features, aspects of the memory cell structure may be implemented with other relative dimensions or quantities of such features in accordance with examples as disclosed herein. In the following description of the processing steps 300, some methods, techniques, processes, and operations may be performed in different orders or at different times. Further, some operations may be left out of the processing steps 300, or other operations may be added to the processing steps 300.

Operations illustrated in and described with reference to FIGS. 3A through 3N may be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 3A illustrates a processing step 300-a associated with forming a stack of materials 305. For example, forming the stack of materials 305 may include depositing alternating layers of a dielectric material 306 and a sacrificial material 307 above a substrate (e.g., an xy-plane upon which materials may be formed), where the substrate (e.g., not shown) may be associated with complementary metal-oxide semiconductor (CMOS) circuitry. In some such examples, depositing the alternating layers may include depositing a layer of the dielectric material 306, then depositing a layer of the sacrificial material 307 above the layer of the dielectric material 406. Accordingly, the dielectric material 306 and the sacrificial material 307 may be similarly deposited to form alternating layers, where the height of the stack of materials 305 may be based on the quantity and height of each of the alternating layers. In some implementations, the dielectric material 306 may be an oxide material (e.g., or similar dielectric material), such as silicon oxide, silicon oxycarbide, silicon oxynitride, or silicon nitride. In some implementations, the sacrificial material 307 may be a variation of nitride. In some cases, the thickness of the dielectric material 306 may be 15 nanometers (nm) to 25 nm. In some cases, the thickness of the sacrificial material 307 may be 15 nm to 25 nm, or some other thickness.

After forming the stack of materials 305, one or more piers 310 may be formed in the stack of materials 305. For example, the piers 310 may be formed based on first forming cavities in the stack of materials 305. The cavities may extend along the z-direction some distance (e.g., from a top surface of the stack of materials 305) toward the substrate (e.g., to a bottom surface of the stack of materials 305), and may be arranged in a grid-like pattern relative to an xy-plane. Forming the cavities may include removing portions of the stack of materials 305 in accordance with the pattern. For example, a mask (e.g., a photolithographic mask) may be formed above the stack of materials 305, where the mask may selectively cover the stack of materials 305 such that the mask may expose the portions of the stack of materials 305 associated with the cavities. In some such examples, the stack of materials 305 may be etched based on the mask, such that the portions of the stack of materials 305 exposed by the mask may be removed. After forming the cavities, the piers 310 may be formed within the cavities. For example, sacrificial material may be deposited into the cavities to form the piers 310 in the stack of materials 305. In some cases, the diameter of the piers 310 may be 80 nm to 120 nm. For example, the diameter of the piers 310 may be 100 nm, or some other diameters.

FIG. 3B illustrates a processing step 300-b associated with forming cell pillars 315 at a quantity of the piers 310. For example, a quantity of the piers 310 may be removed, such that the quantity of piers 310 may be replaced with cell pillars 315. In some cases, removing the quantity of piers 310 may include forming cavities through the stack of materials 305 at the quantity of piers 310 using a selective etching operation configured to remove the sacrificial material of the piers 310. In some examples, a mask may be used to prevent one or more piers 310 from being removed during forming the cell pillars 315. For example, pier 310-a may not be removed during forming the cavities at the quantity of piers 310. After forming the cavities, memory material associated with the cell pillars may be deposited within the cavities to form the cell pillars 315. In some cases, the memory material may be deposited in alternating layers with a dielectric material.

FIG. 3C illustrates a processing step 300-c associated with removing the pier 310-a. For example, the pier 310-a may be removed using the selective etching operation configured to remove the sacrificial material of the pier 310-a. In some examples, a mask may be used to prevent one or more cell pillars 315 from being removed during removing the pier 310-a. In some examples, removing the pier 310-a may include forming a cavity 311 through the stack of materials 305 at the pier 310-a. After removing the pier 310-a, the cavity 311 may be used to remove portions of the sacrificial material 307. That is, the cavity 311 may be used for forming recesses 312 in the layers of the sacrificial material 307. For example, the recesses 312 may extend between the layers of dielectric material 306 along the z-direction, and may extend from the cavity 311 towards the cell pillars 315 adjacent to the cavity 311 along the x-direction. In some examples, portions of the sacrificial material 307 may remain between the layers of dielectric material 306 adjacent to the cell pillars 315 and the recesses 312 after forming the recesses 312. In some cases, the recess depth may be 80 nm to 100 nm, or some other depth.

FIG. 3D illustrates a processing step 300-d associated with forming polysilicon material 320 at the recesses 312. For example, polysilicon material 320 may be deposited within the recesses 312, such that the polysilicon material 320 may extend between the layers of dielectric material 306 along the z-direction, and may extend from the portions of remaining sacrificial material 307 (e.g., adjacent to the cell pillars 315) to the cavity 311 along the x-direction. In some examples, the cavity 311 may be used to deposit the polysilicon material 320 to fill the recesses 312 such that a space (e.g., opening) in the cavity 311 is present. In some such examples, the polysilicon material 320 may be isotropically recessed to leave the isolated polysilicon material 320 in each recess 312. In some examples, the deposition of the polysilicon material 320 may be 15 nm to 25 nm and the recess depth may be 15 nm to 25 nm, or some other depths. In some cases, prior to forming the polysilicon material 320 within the recesses 312, a barrier material 321 may be formed within the recesses 312. For example, the barrier material 321 may be deposited and recessed to a desired thickness (e.g., along the x-direction) adjacent to the remaining sacrificial material 307 along the x-direction. In some cases, the sacrificial material 307 may be a metal oxide film, such as a hafnium oxide (HfO2) film. In some examples, the barrier material 321 may be formed based on converting the sacrificial material 307 to the barrier material 321. In some cases, the sacrificial material 307 may be a silicon oxide film formed by oxidizing silicon nitride. In some examples, the barrier materials 321 may be formed based on growing the barrier material 321 from a surface of the sacrificial material 307 (e.g., by propagating a seed of the barrier material 321). Then, the polysilicon material 320 may be deposited and recessed adjacent to the barrier material 321 up to the cavity 311 along the x-direction. In some implementations, the barrier material may include be a variation of a nitrogen oxide material.

FIG. 3E illustrates a processing step 300-e associated with removing portions of the dielectric material 306. That is, the cavity 311 may be used for forming recesses 313 in the layers of dielectric material 306. In some cases, the depth of the recesses 313 may be 30 nm to 40 nm, or some other depth. For example, the recesses 313 may extend between the polysilicon material 320 at the layers of sacrificial material 307 along the z-direction. Further, the recesses 313 may extend from the cavity 311 towards the cell pillars 315 adjacent to the cavity 311 along the x-direction. In some examples, portions of the dielectric material 306 may remain between the layers of sacrificial material 307 adjacent to the cell pillars 315 and the recesses 313 after forming the recesses 313.

FIG. 3F illustrates a processing step 300-f associated with forming sacrificial material 325 at the recesses 313. For example, the sacrificial material 325 may be deposited and recessed to fill the recesses 313, such that the sacrificial material 325 may extend between the polysilicon material 320 along the z-direction, and may extend from the portions of remaining dielectric material 306 (e.g., adjacent to the cell pillars 315) to the cavity 311 along the x-direction. In some cases, the deposition of the sacrificial material 325 may be 15 nm to 25 nm, and the recess depth of the sacrificial material 325 may be 15 nm to 25 nm, or some other depths. In some examples, the cavity 311 may be used to deposit the sacrificial material 325 within the recesses 313. After forming the sacrificial material 325, the cavity 311 may be filled with a sacrificial material 330. For example, the sacrificial material 330 may be deposited within the cavity 311 such that the sacrificial material 330 may form a pillar of sacrificial material 330 through the stack of materials 305. In some examples, the cavity 311 may be re-etched to planarize the stack of materials 305 (e.g., along a plane in the yz-direction) prior to forming the sacrificial material 330 in the cavity 311. In some implementations, the sacrificial material 325 may be a nitrogen-based material, and the sacrificial material 330 may be an oxide-based material, or some other combination of materials.

FIG. 3G illustrates a processing step 300-g associated with removing at least a portion of the polysilicon material 320 and the sacrificial material 325 from one or more layers of the stack of materials 305. For example, the polysilicon material 320 and the sacrificial material 325 (e.g., at layers of the dielectric material 306 and layers of the sacrificial material 307) above (e.g., relative to the substrate, in the z-direction) a target layer 322 of the polysilicon material 320 may be removed from the memory architecture. In some cases, removing the polysilicon material 320 and the sacrificial material 325 from the layers of the stack of materials 305 above the target layer 322 may include photolithography to open the mask of targeted location, and performing a selective etching operation down to the target layer 322, such that the polysilicon material 320 and the sacrificial material 325 above the target layer 322 are removed. In some examples, removing the polysilicon material 320 and the sacrificial material 325 from the layers of the stack of material 305 above the target layer 322 may not remove the polysilicon material 320 of the target layer 322, nor the sacrificial material 325 below the target layer 322. For example, the polysilicon material 320 and the sacrificial material 325 from the layers of the stack of material 305 above the target layer 322 may be removed in a cyclical etching process. That is, the layers of the polysilicon material 320 and the sacrificial material 325 may be removed sequentially by each layer until the target layer 322 is reached, such that a top layer of the sacrificial material 325 may be removed, then a top layer of the polysilicon material 320 may be removed, and so on. In some examples, the layers of the polysilicon material 320 may be cyclically removed using an etching operation targeting the polysilicon material 320 (e.g., and not affecting other materials of the stack of materials 305). To target all the word line layers depending on the location of the contacts, combination of multiple photolithography and cyclic etching are used. For example, at a certain photolithography mask, 2^{N} cyclic etching is performed while at another photolithography mask 2^{N+1} cyclic etching is performed. By such a ‘binary’ scheme, all or most of the levels of word line layers can have corresponding word line contact structures. In some cases, the sacrificial material 325 may be a silicon nitride material, and etching the sacrificial material 325 may cause erosion of the sacrificial material 307. To avoid such failure, the depth of the recesses 312 and 313 may be controlled to not expose the sacrificial material 307 during cyclic isotropic etching. Likewise, the layers of the sacrificial material 325 may be cyclically removed using another etching operation targeting the sacrificial material 325 (e.g., and ignoring the other materials of the stack of materials 305). In some such examples, the etching operations may be alternated to cyclically remove the layers of the polysilicon material 320 and the sacrificial material 325.

In some implementations, removing the polysilicon material 320 and the sacrificial material 325 from the layers of the stack of materials 305 above the target layer 322 may not remove the barrier material 321 from the recesses 312, nor the sacrificial material 330 from the cavity 311. In some cases, removing the polysilicon material 320 and the sacrificial material 325 may re-form the recesses 312 and the recesses 313 at the layers of the stack of materials 305. For example, removing the polysilicon material 320 may re-form the recesses 312 at layers of the sacrificial material 307, and removing the sacrificial material 325 may re-form the recesses 312 at layers of the dielectric material 306.

As described herein, the target layer 322 may represent an example of a layer of the memory device that is intended to be coupled with a word line contact. For example, one or more memory cells within the target layer 322 may ultimately be coupled with a word line contact that extends through the cavity 311, which may provide for the word line to active or otherwise access the one or more memory cells at the target layer 322 without accessing or otherwise activating memory cells at other layers in the stack.

FIG. 3H illustrates a processing step 300-h associated with doping the polysilicon material 320 at the target layer 322. For example, the target layer 322 of the polysilicon material 320 may be doped using a boron doping process. In some such examples, the target layer 322 of the polysilicon material 320 may be gas-phase doped by exposing the polysilicon material 320 to a boron containing ambient (e.g., dopant) for a quantity of time and at some temperature associated with doping the polysilicon material 320 with boron. In other examples, the target layer 322 may be doped using a similar silicide doping process. The doping may convert the polysilicon material 320 to a doped polysilicon material 323, which may include one or more features or characteristics that are different than the polysilicon material 320. In some cases, rather than doping the polysilicon material 320 at the target layer 322, the polysilicon material 320 may be replaced with a conductive material at the target layer.

FIG. 3I illustrates a processing step 300-i associated with removing the polysilicon material 320 and the sacrificial material 325 from layers of the stack of materials 305. For example, the polysilicon material 320 and the sacrificial material 325 (e.g., at layers of the dielectric material 306 and layers of the sacrificial material 307) below the target layer 322 may be removed from the memory architecture. In some cases, removing the polysilicon material 320 and the sacrificial material 325 from the layers of the stack of material 305 below the target layer 322 may include performing a selective etching operation below the target layer 322, such that the polysilicon material 320 and the sacrificial material 325 below the target layer 322 are removed. In some examples, removing the polysilicon material 320 and the sacrificial material 325 from the layers of the stack of material 305 below the target layer 322 may not remove the barrier material 321 from the recesses 312. Because the material at the target layer 322 was previously doped, the doped polysilicon material 323 at the target layer 322 may not be removed during the selective etching of undoped polysilicon material 320 (e.g., by room temperature tetramethylammonium hydroxide (TMAH) etching), which may target removal of the polysilicon material 320 and the sacrificial material 325.

In some cases, removing the polysilicon material 320 and the sacrificial material 325 may re-form the recesses 312 and the recesses 313 at the layers of the stack of materials 305 that are below the target layer 322. For example, removing the polysilicon material 320 may re-form the recesses 312 at layers of the sacrificial material 307, and removing the sacrificial material 325 may re-form the recesses 312 at layers of the dielectric material 306. Additionally, the cavity 311 may be re-formed by removing the sacrificial material 330 from the memory architecture. In some cases, the polysilicon material 320 and the sacrificial material 325 may be removed based on re-forming the cavity 311, such that the cavity 311 may provide access for manufacturing operations associated with removing the polysilicon material 320 and the sacrificial material 325 from below the target layer 322.

FIG. 3J illustrates a processing step 300-j associated with forming an oxide material 335 in the recesses 312. For example, the oxide material 335 may be deposited within the recesses 312, such that the oxide material 335 may extend between layers of the dielectric material 306 along the z-direction, and may extend from the portions of remaining sacrificial material 307 (e.g., adjacent to the cell pillars 315) to an edge of the dielectric material 306 along the x-direction. That is, the recesses 312 may extend to a depth along the x-direction further than a depth of the recesses 313, such that depositing the oxide material 335 within the recesses 312 may make the oxide material 335 coplanar with the remaining portions of the dielectric material 306. In some examples, the cavity 311 may be used to deposit the oxide material 335 within the recesses 312. After forming the oxide material 335, the cavity 311 and the recesses 313 may be filled with the sacrificial material 330. For example, the sacrificial material 330 may be deposited within the cavity 311 and the recesses 313 such that the sacrificial material 330 may form a pillar of sacrificial material 330 through the stack of materials 305. In some examples, the oxide material 335 may be deposited and subsequently etched to be coplanar with the remaining portions of the dielectric material 306 before the sacrificial material 330 is deposited. In some cases, the sacrificial material 330 may be a silicon oxide based material or a doped silicon oxide material, such as boron-phosphorous silicate glass.

FIG. 3K illustrates a processing step 300-k associated with metalizing the sacrificial material 307. For example, the sacrificial material 307 in the layers of the stack of materials 305 may be replaced with a conductive material 340. That is, the layers of the sacrificial material 307 may be exhumed to remove the sacrificial material 307 from the stack of materials 305 (e.g., from the trench in the stack of materials 305 not shown in FIG. 3K). Then, the conductive material 340 may be deposited at the layers of the stack of materials 305 otherwise associated with the sacrificial material 307. As a result of the processing step 300-k, the stack of materials 305 may include alternating layers of the dielectric material 306 and the conductive material 340. In some cases, the barrier material 321 may protect the oxide material 335 (e.g., and the target layer 322 of the doped polysilicon material 323) from being removed during metalizing (e.g., the exhume of) the sacrificial material 307, such that metalizing the sacrificial material 307 may not remove the barrier material 321 from the stack of materials 305. In some cases, the conductive material 340 may be a tungsten material, a molybdenum material, a titanium alloy material, or any combination thereof. In some cases, the processing step 300-k may include depositing high dielectric constant film or metal oxide film prior to the conducting material deposition. In some examples, the conductive material 340 may form word lines, such that each layer of the conductive material 340 may be associated with a respective word line.

FIG. 3L illustrates a processing step 300-l associated with removing the sacrificial material 330 from the stack of materials 305. For example, the sacrificial material 330 may be removed such that the cavity 311 is re-formed. Removing the sacrificial material 330 from the stack of materials 305 may not remove the target layer 322 of the doped polysilicon material 323 from the stack of materials 305.

FIG. 3M illustrates a processing step 300-m associated with removing the doped polysilicon material 323. For example, the doped polysilicon material 323 may be removed from the target layer 322 of the stack of materials 305 by hot TMAH wet etching. In some cases, the barrier material 321 at the target layer 322 may also be removed by diluted hydrofluoric acid after removing the doped polysilicon material 323. In some cases, removing the doped polysilicon material 323 and the barrier material 321 at the target layer 322 may re-form the recess 312 at the target layer 322. In some such cases, the recess 312 at the target layer 322 may extend up to the conductive material 340 (e.g., adjacent to the cell pillars 315) along the x-direction.

FIG. 3N illustrates a processing step 300-n associated with forming a conductive pillar 345 within the cavity 311 and the recess 312. For example, conductive material associated with the conductive pillar 345 may be deposited within the cavity 311 and the recess 312. Depositing the conductive material in the cavity 311 and the recess 312 may include precleaning to expose clean surface of the conductive material 340 (e.g., which may include removal of a high dielectric constant film or metal oxide film) and depositing the conductive material within the recess 312 (e.g., otherwise associated with the doped polysilicon material 320). For example, the conductive material may be deposited within the recess 312 at the target layer 322 to form a conductive pillar 345 that is in contact with the conductive material 340 at the target layer 322, but is not in contact with the conductive material 340 at any other layers of the stack. The conductive pillar 345 may form a word line contact pillar for the memory architecture, where the conductive pillar 345 may be configured to couple a word line at the target layer 322 (e.g., the conductive material 340) with the word line contact. For example, the word line contact pillar may be configured to couple with a string driver (e.g., below the memory architecture) and the word line at the target layer 322, thereby coupling the word line at the target layer 322 with the string driver to access one or more memory cells that are coupled with the word line at the target layer.

Implementing the processing steps 300 may support forming string drivers in groups distributed below the memory architecture. For example, forming word line contacts alongside pillars of the memory architecture may enable similar processes for forming cell pillars to be used in forming word line contact pillars, not adding another high aspect ratio contact etching. Also, the size and the taper of the word line contacts may be improved. For example, cyclic etching processes may form word line contacts at target layers of the memory architecture without forming a staircase region otherwise associated with forming word line contacts. That is, the process for forming the memory architecture may consolidate one or more operations associated with manufacturing the memory architecture, which may be relatively cost effective and simple to implement (e.g., compared to previous processes).

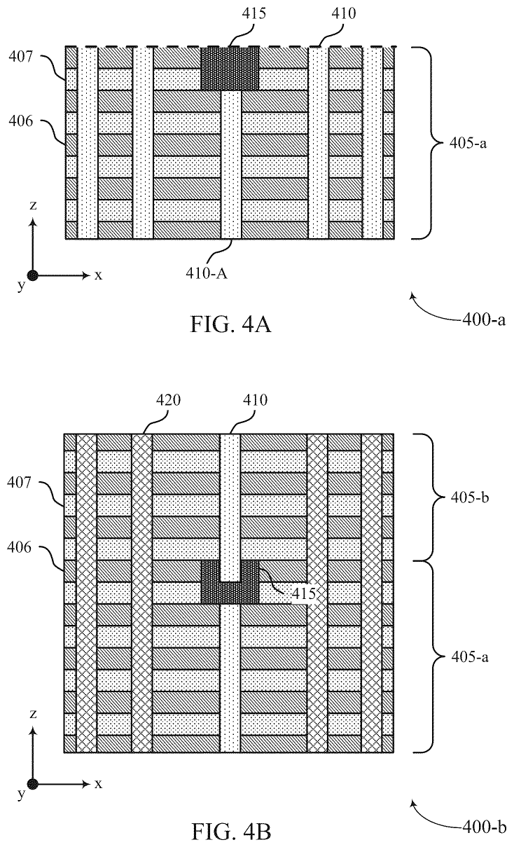

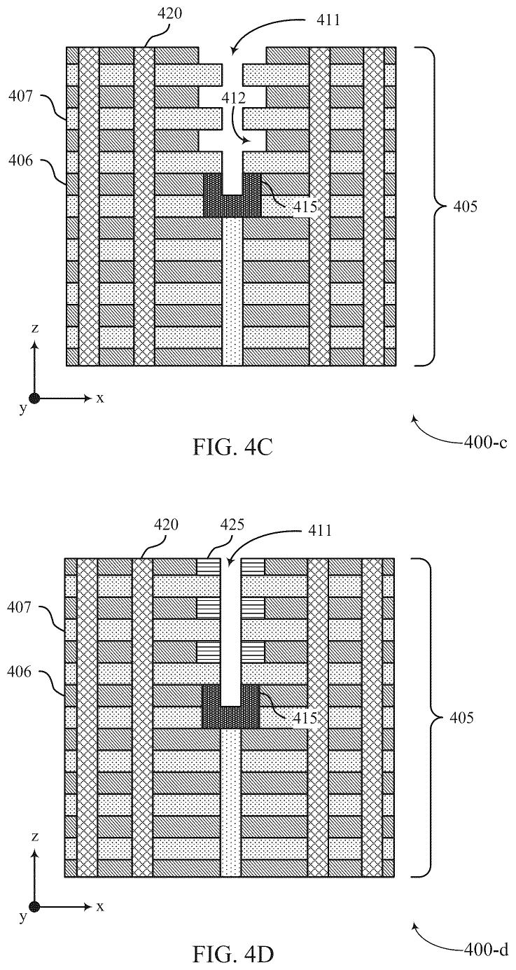

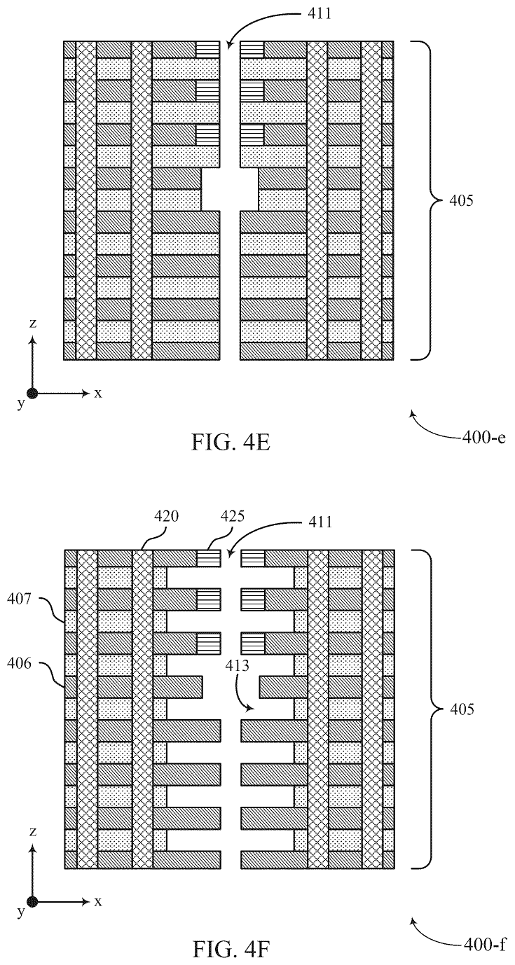

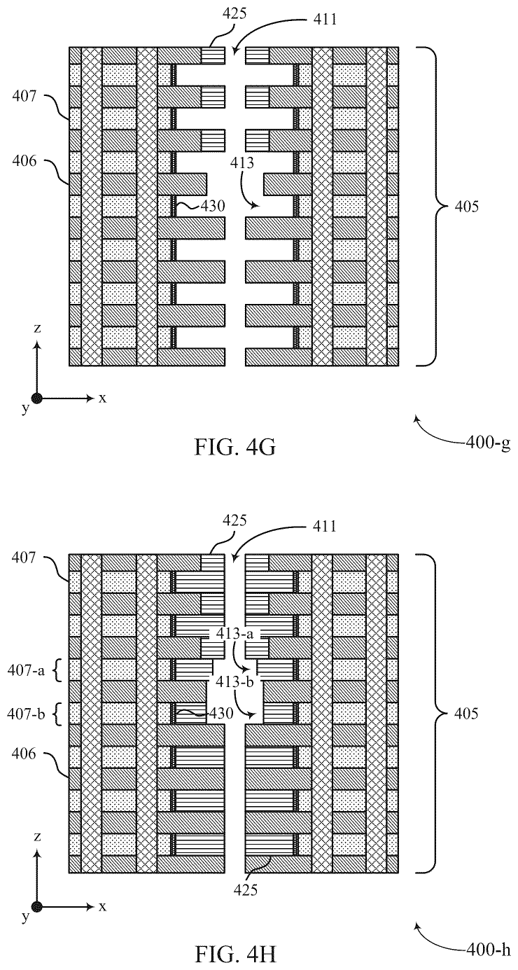

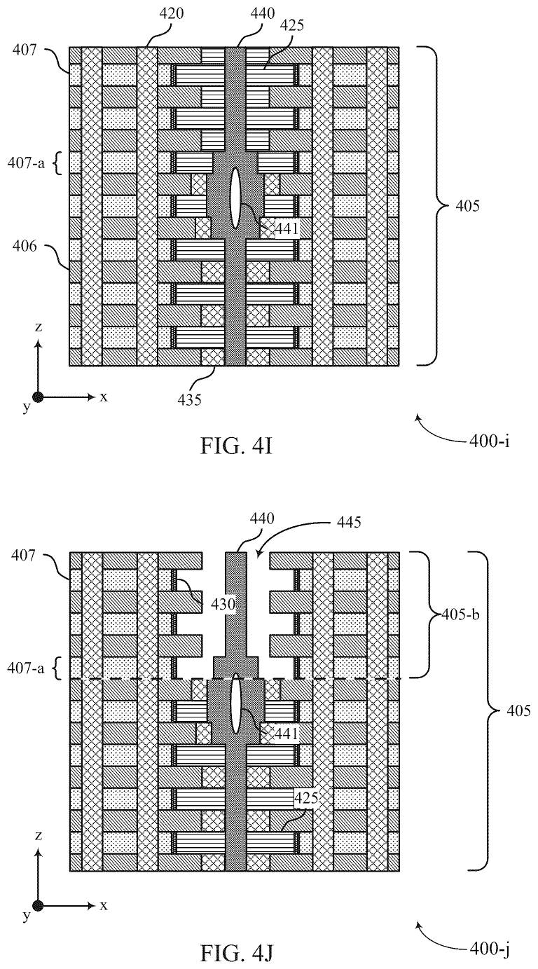

FIGS. 4A through 4J show examples of processing steps 400 that support distributed string drivers under an array in accordance with examples as disclosed herein. FIGS. 4A through 4J show various cross-sectional views of a memory architecture, which may be an example of a memory architecture 200, as described with reference to FIG. 2. The processing steps 400 may illustrate aspects of manufacturing operations for fabricating aspects of memory architecture, which may be implemented in a memory device or a memory array, such as a memory device 100, as described with reference to FIG. 1. The processing steps 400 may illustrate operations associated with implementing string drivers in groups distributed below the memory architecture by forming word line contacts alongside pillars of the memory architecture. For example, cyclic etching processes may form word line contacts at target layers of the memory architecture without forming a staircase region. That is, the process for forming the memory architecture may consolidate one or more operations associated with manufacturing the memory architecture, which may be relatively cost effective and simple to implement (e.g., compared to previous processes).

For illustrative purposes, aspects of the memory architecture may be described with reference to an x-direction, a y-direction, and a z-direction of the illustrated coordinate systems. For example, processing steps 400-a, 400-b, 400-c, 400-d, 400-c, 400-f, 400-g, 400-h, 400-i, and 400-j illustrate the memory architecture from cross-sectional views in an xz-plane, where the memory architecture extends a distance along the y-direction into the page. Although the processing steps 400 illustrate examples of relative dimensions and quantities of various features, aspects of the memory cell structure may be implemented with other relative dimensions or quantities of such features in accordance with examples as disclosed herein. In the following description of the processing steps 400, some methods, techniques, processes, and operations may be performed in different orders or at different times. Further, some operations may be left out of the processing steps 400, or other operations may be added to the processing steps 400.

Operations illustrated in and described with reference to FIGS. 4A through 4J may be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 4A illustrates a processing step 400-a for forming a stack of materials 405. For example, forming the stack of materials 405 may include forming the stack of materials 405-a, and forming the stack of materials 405-b, where the stack of materials 405-a and the stack of materials 405-b are portions of the stack of materials 405. In some such examples, the stack of materials 405-b may be formed above the stack of materials 405-a (e.g., along the z-direction), and at different operations (e.g., the stack of materials 405-b may be formed after forming the stack of materials 405-a).

Forming the stack of materials 405-a may include depositing alternating layers of a dielectric material 406 and a sacrificial material 407 above a substrate (e.g., an xy-plane upon which materials may be formed), where the substrate (e.g., not shown) may be associated with complementary metal-oxide semiconductor (CMOS) circuitry. In some such examples, depositing the alternating layers may include depositing a layer of the dielectric material 406, then depositing a layer of the sacrificial material 407 above the layer of the dielectric material 406. Accordingly, the dielectric material 406 and the sacrificial material 407 may be similarly deposited to form alternating layers, where the height of the stack of materials 405 may be based on the quantity and height of each of the alternating layers. In some implementations, the dielectric material 406 may be an oxide material (e.g., or similar dielectric material), such as silicon oxide, silicon oxycarbide, silicon oxynitride, or silicon nitride. In some implementations, the sacrificial material 407 may be a variation of nitride.

After forming the stack of materials 405-a, piers 410 may be formed in the stack of materials 405-a. For example, the piers 410 may be formed based on first forming cavities in the stack of materials 405-a. The cavities may extend along the z-direction some distance (e.g., from a top surface of the stack of materials 405-a) toward the substrate (e.g., to a bottom surface of the stack of materials 405-a), and may be arranged in a grid-like pattern relative to an xy-plane. Forming the cavities may include removing portions of the stack of materials 405-a in accordance with the pattern. For example, a mask (e.g., a photolithographic mask) may be formed above the stack of materials 405-a, where the mask may selectively cover the stack of materials 405-a such that the mask may expose the portions of the stack of materials 405-a associated with the cavities. In some such examples, the stack of materials 405-a may be etched based on the mask, such that the portions of the stack of materials 405-a exposed by the mask may be removed. After forming the cavities, the piers 410 may be formed within the cavities. For example, sacrificial material may be deposited into the cavities to form the piers 410 in the stack of materials 305-a.

After forming the piers 410, a plug 415 may be formed. Forming the plug 415 may include removing a portion of a pier 410-a, and portions of the layers of dielectric material 406 and sacrificial material 407 adjacent to the pier 410-a (e.g., along the x-direction). For example, the portion of the pier 410-a extending the length of the top two layers of the stack of materials 405-a along the z-direction may be removed. Likewise, a portion of the topmost layer of the dielectric material 406 adjacent to the pier 410-a, and a portion of the topmost layer of the sacrificial material 407 adjacent to the pier 410-a may be removed from the stack of materials 405-a to form a cavity. After forming the cavity, the plug 415 may be deposited into the cavity. In some cases, the plug 415 may include a barrier material.

FIG. 4B illustrates a processing step 400-b associated with forming the stack of materials 405. For example, forming the stack of materials 405 may include forming the stack of materials 405-b above the stack of materials 405-b. Forming the stack of materials 405-b may include depositing alternating layers of the dielectric material 406 and the sacrificial material 407 above a topmost layer of the stack of materials 405-a. After forming the stack of materials 405-b, the piers 410 may be formed in the stack of materials 405-b. For example, the piers 410 may be formed based on first forming cavities in the stack of materials 405-b above the piers 410 in the stack of materials 405-a. That is, the cavities in the stack of material 405-b may be formed concentrically and connect with the piers 410 in the stack of materials 405-a. After forming the cavities, the piers 410 may be formed within the cavities. For example, the sacrificial material may be deposited into the cavities to form the piers 410 in the stack of materials 305-b.

After forming the stack of materials 405-b, cell pillars 420 may be formed at a quantity of the piers 410. For example, a quantity of the piers 410 may be removed, such that the quantity of piers 410 may be replaced with cell pillars 420. In some cases, removing the quantity of piers 410 may include forming cavities through the stack of materials 405 at the quantity of piers 410 using a selective etching operation configured to remove the sacrificial material of the piers 410. In some examples, a mask may be used to prevent one or more piers 410 from being removed during forming the cell pillars 420. For example, the pier 410-a may not be removed during forming the cavities at the quantity of piers 410. After forming the cavities, memory material associated with the cell pillars may be deposited within the cavities to form the cell pillars 420. In some cases, the memory material may be deposited in alternating layers with a dielectric material.

FIG. 4C illustrates a processing step 400-c associated with removing a portion of the pier 410-a. For example, a portion of the pier 410-a above the plug 415 along the z-direction may be removed by lithograph and etching process for the word line contacts targeting word lines in the stack of materials 405. In some examples, removing the portion of the pier 410-a may include using the selective etching operation configured to remove the sacrificial material of the pier 410-a. In some examples, a mask may be used to prevent one or more cell pillars 420 from being removed during removing the portion of the pier 410-a. In some examples, removing the portion of the pier 410-a may include forming a cavity 411 through the stack of materials 405 down to the plug 415 (e.g., along the z-direction). In some implementations, forming the cavity 411 may include removing a portion of the plug 415. After removing the portion of the pier 410-a, the cavity 411 may be used to remove portions of the dielectric material 406 above the plug 415. That is, the cavity 411 may be used for forming recesses 412 in the layers of the dielectric material 406 above the plug 415. For example, the recesses 412 may extend between the layers of sacrificial material 407 along the z-direction, and may extend from the cavity 411 towards the cell pillars 420 adjacent to the cavity 411 along the x-direction. In some examples, portions of the dielectric material 406 may remain between the layers of sacrificial material 407 adjacent to the cell pillars 420 after forming the recesses 412. In some cases, a depth of the recesses 412 may be 30 nm to 40 nm, or some other depth.

FIG. 4D illustrates a processing step 400-d associated with forming polysilicon material 425 at the recesses 412. For example, polysilicon material 425 may be deposited and etched back within the recesses 412, such that the polysilicon material 425 may extend between the layers of sacrificial material 407 along the z-direction, and may extend from the portions of remaining dielectric material 406 (e.g., adjacent to the cell pillars 420) to the cavity 411 along the x-direction. In some examples, the cavity 411 may be used to deposit the polysilicon material 425 within the recesses 412 above the plug 415.

FIG. 4E illustrates a processing step 400-e associated with removing plug 415 from the stack of materials 405. For example, the plug 415 may be removed via a selective etching operation targeting the plug 415 for removal from the stack of materials 405. After removing the plug 415, the pier 410-a may be removed from the stack of materials 405. For example, the remaining portion of the pier 410-a below the plug 415 may be removed from the stack of materials 405.

FIG. 4F illustrates a processing step 400-f associated with removing portions of the sacrificial material. That is, after removing the pier 410-a, the cavity 411 may be used to remove portions of the sacrificial material 407. For example, the cavity 411 may be used for forming recesses 413 in the layers of the sacrificial material 407. The recesses 413 may extend between the layers of dielectric material 406 (e.g., or the layers of the polysilicon material 425) along the z-direction, and may extend from the cavity 411 towards the cell pillars 420 adjacent to the cavity 411 along the x-direction. In some examples, portions of the sacrificial material 407 may remain between the layers of dielectric material 406 adjacent to the cell pillars 420 after forming the recesses 413. In some cases, a depth of the recesses 413 may be 80 nm to 120 nm, or some other depth.

FIG. 4G illustrates a processing step 400-g associated with forming a barrier material 430 within the recesses 413. For example, the barrier material 430 may be deposited and etched back to a desired thickness (e.g., along the x-direction) adjacent to the remaining sacrificial material 407 along the x-direction. In some examples, the cavity 411 may be used to deposit the barrier material 430 within the recesses 413. After forming the barrier material 430, the recesses 413 may remain between the layers of the dielectric material 406. In some implementations, the barrier material 430 may include be a variation of a nitrogen oxide material. In some cases, the sacrificial material 407 may be a metal oxide film, such as a hafnium oxide film, or a silicon oxide film formed by oxidizing silicon nitride.

FIG. 4H illustrates a processing step 400-h associated with forming the polysilicon material 425 at the recesses 413. For example, polysilicon material 425 may be deposited and etched back within the recesses 413, such that the polysilicon material 425 may extend between the layers of dielectric material 406 along the z-direction, and may extend from the barrier material 430 to the cavity 411 along the x-direction. In some examples, the cavity 411 may be used to deposit the polysilicon material 425 within the recesses 413. In some implementations, a recess 413-a associated with a layer 407-a of the sacrificial material 407 within the stack of materials 405 may not extend to the cavity 411. In some such implementations, the polysilicon material 425 may be deposited within the recess 413-a, such that the polysilicon material 425 may not extend from the barrier material 430 to the cavity 411. Instead, the polysilicon material 425 may extend a distance from the barrier material 430 towards the cavity 411, such that the polysilicon material 425 at the layer 407-a does not extend to a same distance as the polysilicon material 425 in other layers. In some implementations, a recess 413-b associated with a layer 407-b of the sacrificial material 407 within the stack of materials 405 may not extend to the cavity 411. In some such implementations, the polysilicon material 425 may be deposited within the recess 413-b, such that the polysilicon material 425 may not extend from the barrier material 430 to the cavity 411. Instead, the polysilicon material 425 may extend a distance from the barrier material 430 towards the cavity 411, such that the polysilicon material 425 at the layer 407-b does not extend to a same distance as the polysilicon material 425 in other layers. In some examples, the portions of the polysilicon material 425 formed in the recesses 412 and 413 may be effectively united above the level where the recesses 412 were created.

FIG. 4I illustrates a processing step 400-i associated with removing portions of the dielectric material 406 below the layer 407-a. That is, the cavity 411 may be used for forming recesses in the layers of the dielectric material 406 below the layer 407-a. For example, the recesses may extend between the polysilicon material 425 associated with the layers of sacrificial material 407 along the z-direction, and may extend from the cavity 411 towards the cell pillars 420 adjacent to the cavity 411 along the x-direction. In some examples, portions of the dielectric material 406 may remain between the layers of sacrificial material 407 adjacent to the cell pillars 420 after forming the recesses. In some implementations, the recesses may extend a distance from the cavity 411 toward the cell pillars 420, such that the distance corresponds to the depth of the recesses 412. After forming the recesses, a sacrificial material 435 may be formed within the recesses. For example, the sacrificial material 435 may be deposited and etched back within the recesses, such that the sacrificial material 435 may extend between the layers of sacrificial material 407 along the z-direction, and may extend from the portions of remaining dielectric material 406 (e.g., adjacent to the cell pillars 420) to the cavity 411 along the x-direction. In some examples, the cavity 411 may be used to deposit the sacrificial material 435 within the recesses below the layer 407-a. After forming the sacrificial material 435 within the recesses below the layer 407-a, the cavity 411 may be filled with a sacrificial material 440. For example, the cavity 411 and the recesses 413 not filled with the polysilicon material 425 may be filled with the sacrificial material 440. In some cases, forming the sacrificial material 440 within the cavity 411 may include refraining from filling a portion of the cavity 411 with the sacrificial material 440, such that an internal cavity 441 may remain within the sacrificial material 440. In some implementations, the sacrificial material 435 may be a nitrogen-based material, and the sacrificial material 440 may be an oxide-based material, or doped silicon oxide material such as boron-phosphorous silicate glass.

FIG. 4J illustrates a processing step 400-j associated with removing the polysilicon material 425 from the stack of materials 405 at and above the layer 407-a. For example, the polysilicon material 425 may be removed from the stack of materials 405 at the layer 407-a and above the layer 407-a, forming a cavity 445 within the stack of materials 405. In some cases, the polysilicon material 425 may be removed from the stack of materials 405-b based on the stack of materials 405-b being at and above the layer 407-a. In some examples, removing the polysilicon material 425 from the stack of materials 405 at and above the layer 407-a may not remove the barrier material 430 from the layers of the sacrificial material 407.

Implementing the processing steps 400 may support forming string drivers in groups distributed below the memory architecture. For example, performing the processing steps 400 may enable splitting the stack of material 405, such that other operations may be selectively formed on the stack of material 405-b. In some cases, operations associated with the processing steps 300 may be formed as a result of splitting the stack of materials 405, such that the processing steps 300 may target the stack of materials 405-b. In some cases, the processing steps 400 may support forming word line contacts alongside pillars of the memory architecture which may enable similar processes for forming cell pillars to be used in forming word line contact pillars. The quantity of cycles of etching processes can be reduced owing to effective skipping of the portion of the stack of materials 405-b for word line contacts targeting word line levels in the lower portion of the stack of materials 405-a. For example, cyclic etching processes may form word line contacts at target layers of the memory architecture without forming a staircase region otherwise associated with forming word line contacts. That is, the process for forming the memory architecture may consolidate one or more operations associated with manufacturing the memory architecture, which may be relatively cost effective and simple to implement (e.g., compared to previous processes).

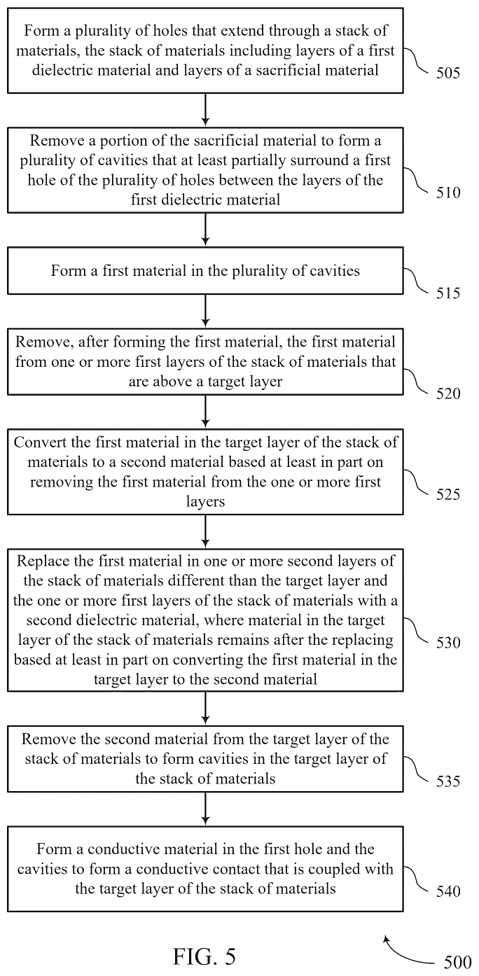

FIG. 5 shows a flowchart illustrating a method or methods 500 that supports distributed string drivers under an array in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include forming a plurality of holes that extend through a stack of materials, the stack of materials including layers of a first dielectric material and layers of a sacrificial material.

At 510, the method may include removing a portion of the sacrificial material to form a plurality of cavities that at least partially surround a first hole of the plurality of holes between the layers of the first dielectric material.

At 515, the method may include depositing a first material in the plurality of cavities.

At 520, the method may include removing, after depositing the first material, the first material from one or more first layers of the stack of materials that are above a target layer.

At 525, the method may include converting the first material in the target layer of the stack of materials to a second material based at least in part on removing the first material from the one or more first layers.

At 530, the method may include replacing the first material in one or more second layers of the stack of materials different than the target layer and the one or more first layers of the stack of materials with a second dielectric material, where material in the target layer of the stack of materials remains after the replacing based at least in part on converting the first material in the target layer to the second material.

At 535, the method may include removing the second material from the target layer of the stack of materials to form cavities in the target layer of the stack of materials.

At 540, the method may include depositing a conductive material in the first hole and the cavities to form a conductive contact that is coupled with the target layer of the stack of materials.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by a one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a plurality of holes that extend through a stack of materials, the stack of materials including layers of a first dielectric material and layers of a sacrificial material; removing a portion of the sacrificial material to form a plurality of cavities that at least partially surround a first hole of the plurality of holes between the layers of the first dielectric material; forming a first material in the plurality of cavities; removing, after forming the first material, the first material from one or more first layers of the stack of materials that are above a target layer; converting the first material in the target layer of the stack of materials to a second material based at least in part on removing the first material from the one or more first layers; replacing the first material in one or more second layers of the stack of materials different than the target layer and the one or more first layers of the stack of materials with a second dielectric material, where material in the target layer of the stack of materials remains after the replacing based at least in part on converting the first material in the target layer to the second material; removing the second material from the target layer of the stack of materials to form cavities in the target layer of the stack of materials; and forming a conductive material in the first hole and the cavities to form a conductive contact that is coupled with the target layer of the stack of materials.

Aspect 2: The method or apparatus of aspect 1, further including operations, features, circuitry, logic, means, or instructions, or any combination thereof for forming the stack of materials based at least in part on forming the layers of the first dielectric material and the layers of the sacrificial material in an alternating pattern.

Aspect 3: The method or apparatus of any of aspects 1 through 2, further including operations, features, circuitry, logic, means, or instructions, or any combination thereof for forming a memory material in at least two second holes of the plurality of holes based at least in part on forming the plurality of holes and where removing the portion of the sacrificial material is based at least in part on forming the memory material in the at least two second holes.

Aspect 4: The method or apparatus of any of aspects 1 through 3, further including operations, features, circuitry, logic, means, or instructions, or any combination thereof for removing the second material from the target layer of the stack of materials to form a plurality of cavities in the target layer of the stack of materials; and forming a barrier material in the plurality of cavities based at least in part on removing the portion of the sacrificial material and where forming the first material in the plurality of cavities is based at least in part on forming the barrier material.

Aspect 5: The method or apparatus of any of aspects 1 through 4, where converting the first material in the target layer of the stack of materials to the second material includes operations, features, circuitry, logic, means, or instructions, or any combination thereof for doping the first material in accordance with a Boron doping or silicidation process.

Aspect 6: The method or apparatus of any of aspects 1 through 5, where replacing the first material in the one or more second layers of the stack of materials with the second dielectric material includes operations, features, circuitry, logic, means, or instructions, or any combination thereof for removing the first material from the one or more second layers of the stack of materials to form a plurality of second cavities that at least partially surround the first hole between the layers of the first dielectric material and forming the second dielectric material in the plurality of second cavities.

Aspect 7: The method or apparatus of aspect 6, further including operations, features, circuitry, logic, means, or instructions, or any combination thereof for forming a second sacrificial material in the first hole based at least in part on forming the second dielectric material in the plurality of second cavities, where the second dielectric material in the plurality of second cavities is in contact with the second sacrificial material.

Aspect 8: The method or apparatus of any of aspects 6 through 7, where removing the first material from the one or more second layers of the stack of materials is based at least in part on an etchant and the second material resists the etchant.

Aspect 9: The method or apparatus of any of aspects 1 through 8, further including operations, features, circuitry, logic, means, or instructions, or any combination thereof for removing a second portion of the sacrificial material to form a plurality of second cavities between the layers of the first dielectric material; forming a second conductive material in the plurality of second cavities; and where removing the second material from the target layer of the stack of materials is based at least in part on forming the second conductive material in the plurality of second cavities, the second conductive material at the target layer of the stack of materials exposed via the first hole based at least in part on removing the second material from the target layer of the stack of materials.

Aspect 10: The method or apparatus of any of aspects 1 through 9, further including operations, features, circuitry, logic, means, or instructions, or any combination thereof for forming a second sacrificial material within the plurality of holes; removing the second sacrificial material from a subset of the plurality of holes, the subset of the plurality of holes excluding the first hole; forming a memory material in the subset of the plurality of holes based at least in part on removing the second sacrificial material, where the memory material is in contact with the conductive material at the target layer of the stack of materials based at least in part on depositing the conductive material; and removing the second sacrificial material from the first hole based at least in part on forming the memory material, where removing the portion of the sacrificial material via the first hole is based at least in part on removing the second sacrificial material from the first hole.

Aspect 11: The method or apparatus of any of aspects 1 through 10, where the first dielectric material and the second dielectric material include an oxide material.

Aspect 12: The method or apparatus of any of aspects 1 through 11, where the sacrificial material includes a nitride material.

Aspect 13: The method or apparatus of any of aspects 1 through 12, where the first material includes a polysilicon material and the second material includes a Boron-doped polysilicon material or a polysilicon material subjected to a silicidation process.

Aspect 14: The method or apparatus of any of aspects 1 through 13, where the conductive material includes a tungsten material, a molybdenum material, or a titanium alloy material, or a combination thereof.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 15: A memory device, including: a first layer including a plurality of string driver regions, where each string driver region extends in a first direction and is separated from other string driver regions of the plurality of string driver regions in a second direction, and where each string driver region includes a respective one or more string drivers and a respective one or more contacts; and one or more second layers positioned above the first layer, each second layer of the one or more second layers including a plurality of contact regions and a plurality of array regions, where each contact region of the plurality of contact regions is positioned above a respective string driver region, and where each array region includes: a plurality of bit lines that extend in the first direction in the one or more second layers, where the plurality of bit lines is positioned above the plurality of string driver regions in the first layer; and one or more word lines that extend in the second direction, where each word line is coupled with a respective string driver via a contact region of the respective pair of contact regions.

Aspect 16: The memory device of aspect 15, where each array region of the plurality of array regions is positioned between a respective pair of contact regions in the second direction.

Aspect 17: The memory device of any of aspects 15 through 21, further including a substrate, where the first layer is positioned above the substrate and between the one or more second layers and the substrate.

Aspect 18: The memory device of any of aspects 15 through 22, wherein each layer of the one or more second layers comprises one or more respective word lines that are continuous across the plurality of array regions.

Aspect 19: The memory device of aspect 15 through 23, wherein each string driver region of the plurality of string driver regions in the first layer is coupled with a respective set of word lines in a respective second layer of the one or more second layers.

Aspect 20: The memory device of any of aspects 15 through 24, wherein each string driver region of the plurality of string driver regions in the first layer has a first width, and each contact region of the plurality of contact regions in the one or more second layers has a second width that is less than the first width.

Aspect 21: The memory device of aspect 15 through 19, where each contact region of the plurality of contact regions in the one or more second layers includes two sets of word line contacts that extend from the respective one or more contacts positioned below the respective contact region in the first layer.

Aspect 22: The memory device of any of aspects 15 through 21, where each word line is coupled with the respective string driver via a respective contact that extends from a respective string driver region in the first layer through a respective contact region in the one or more second layers.

Aspect 23: The memory device of any of aspects 15 through 22, further including: a page buffer positioned in the first layer and including a plurality of portions of the page buffer, where each portion of the page buffer extends between a respective pair of string driver regions in the second direction.

Aspect 24: The memory device of aspect 23, where the plurality of bit lines are coupled with a respective portion of the page buffer, the respective portion positioned between the respective pair of contact regions in the second direction.

Aspect 25: The memory device of any of aspects 23 through 24, where each portion of the page buffer extends along the first direction adjacent to the respective pair of string driver regions in the second direction.

An apparatus is described. The following provides an overview of aspects of the apparatus as described herein:

Aspect 26: A memory device, including: a first layer and including a plurality of string driver regions, where each string driver region extends in a first direction and is separated from other string driver regions of the plurality of string driver regions in a second direction, and where each string driver region of the plurality of string driver regions includes a respective one or more string drivers and a respective one or more contacts; and a plurality of array layers positioned above the first layer, the plurality of array layers including a plurality of contact regions and a plurality of array regions, where each contact region of the plurality of contact regions is positioned above a respective string driver region and includes: a conductive contact that extends in a third direction from the respective one or more contacts in the first layer through the plurality of array layers, where the conductive contact includes conductive material that extends in the second direction in a target array layer of the plurality of array layers, and where the conductive contact is coupled with a first word line in a first array region of the plurality of array regions at the target array layer based at least in part on the conductive material extending in the second direction in the target array layer; and where each array region of the plurality of array regions is positioned between a respective pair of contact regions in the second direction and includes: a plurality of bit lines that extend in the first direction in each second layer of the plurality of array layers, the plurality of bit lines positioned above the plurality of string driver regions in the first layer; and one or more word lines that extend in the second direction in each array layer of the plurality of array layers.

Aspect 27: The memory device of aspect 26, further including a substrate, where the first layer is positioned above the substrate.

Aspect 28: The memory device of aspect 26, where each array region of the plurality of array regions further includes: a plurality of memory cells stacked in the third direction, where the one or more word lines are coupled with the plurality of memory cells.

Aspect 29: The memory device of aspect 28, where the target array layer includes at least one memory cell of the plurality of memory cells that is coupled with the conductive contact via at least one word line of the one or more word lines.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a first layer comprising a plurality of string driver regions, wherein each string driver region extends in a first direction and is separated from other string driver regions of the plurality of string driver regions in a second direction, and wherein each string driver region comprises a respective one or more string drivers and a respective one or more contacts; and
one or more second layers positioned above the first layer, each second layer of the one or more second layers comprising a plurality of contact regions and a plurality of array regions, wherein each contact region of the plurality of contact regions is positioned above a respective string driver region, and wherein each array region comprises:
a plurality of bit lines that extend in the first direction in the one or more second layers, wherein the plurality of bit lines is positioned above the plurality of string driver regions in the first layer; and
one or more word lines that extend in the second direction, wherein each word line is coupled with a respective string driver via a contact region of the respective pair of contact regions.

2. The memory device of claim 1, wherein each array region of the plurality of array regions is positioned between a respective pair of contact regions in the second direction.

3. The memory device of claim 1, further comprising:
a substrate, wherein the first layer is positioned above the substrate and between the one or more second layers and the substrate.

4. The memory device of claim 1, wherein each layer of the one or more second layers comprises one or more respective word lines that are continuous across the plurality of array regions.

5. The memory device of claim 1, wherein each string driver region of the plurality of string driver regions in the first layer is coupled with a respective set of word lines in a respective second layer of the one or more second layers.

6. The memory device of claim 1, wherein each string driver region of the plurality of string driver regions in the first layer has a first width, and each contact region of the plurality of contact regions in the one or more second layers has a second width that is less than the first width.

7. The memory device of claim 1, wherein each contact region of the plurality of contact regions in the one or more second layers comprises at least one set of word line contacts that extends from the respective one or more contacts positioned below the respective contact region in the first layer.

8. The memory device of claim 1, wherein each word line is coupled with the respective string driver via a respective contact that extends from a respective string driver region in the first layer through a respective contact region in the one or more second layers.

9. The memory device of claim 1, further comprising:
a page buffer positioned in the first layer and comprising a plurality of portions of the page buffer, wherein each portion of the page buffer extends between a respective pair of string driver regions in the second direction.

10. The memory device of claim 9, wherein the plurality of bit lines are coupled with a respective portion of the page buffer, the respective portion positioned between the respective pair of contact regions in the second direction.

11. The memory device of claim 9, wherein each portion of the page buffer extends along the first direction adjacent to the respective pair of string driver regions in the second direction.

12. A method of manufacturing a memory device, comprising:
forming a plurality of holes that extend through a stack of materials, the stack of materials comprising layers of a first dielectric material and layers of a sacrificial material;
removing a portion of the sacrificial material to form a plurality of cavities that at least partially surround a first hole of the plurality of holes between the layers of the first dielectric material;
forming a first material in the plurality of cavities;
removing, after forming the first material, the first material from one or more first layers of the stack of materials that are above a target layer;
converting the first material in the target layer of the stack of materials to a second material based at least in part on removing the first material from the one or more first layers;
replacing the first material in one or more second layers of the stack of materials different than the target layer and the one or more first layers of the stack of materials with a second dielectric material, wherein material in the target layer of the stack of materials remains after the replacing based at least in part on converting the first material in the target layer to the second material; and
forming a conductive material in the first hole to form a conductive contact that is coupled with the target layer of the stack of materials.

13. The method of claim 12, further comprising:
forming the stack of materials based at least in part on forming the layers of the first dielectric material and the layers of the sacrificial material in an alternating pattern.

14. The method of claim 12, further comprising:
forming a memory material in at least two second holes of the plurality of holes based at least in part on forming the plurality of holes,
wherein removing the portion of the sacrificial material is based at least in part on forming the memory material in the at least two second holes.

15. The method of claim 12, further comprising:
removing the second material from the target layer of the stack of materials to form a plurality of cavities in the target layer of the stack of materials; and
forming a barrier material in the plurality of cavities based at least in part on removing the portion of the sacrificial material,
wherein forming the first material in the plurality of cavities is based at least in part on forming the barrier material.

16. The method of claim 12, wherein converting the first material in the target layer of the stack of materials to the second material comprises:
doping the first material in accordance with a Boron doping or silicidation process.

17. The method of claim 12, wherein replacing the first material in the one or more second layers of the stack of materials with the second dielectric material comprises:
removing the first material from the one or more second layers of the stack of materials to form a plurality of second cavities that at least partially surround the first hole between the layers of the first dielectric material; and
forming the second dielectric material in the plurality of second cavities.

18. The method of claim 17, further comprising:
forming a second sacrificial material in the first hole based at least in part on forming the second dielectric material in the plurality of second cavities, wherein the second dielectric material in the plurality of second cavities is in contact with the second sacrificial material.

19. The method of claim 17, wherein:
removing the first material from the one or more second layers of the stack of materials is based at least in part on an etchant, and
the second material resists the etchant.

20. The method of claim 12, further comprising:
removing a second portion of the sacrificial material to form a plurality of second cavities between the layers of the first dielectric material; and
forming a second conductive material in the plurality of second cavities,
wherein removing the second material from the target layer of the stack of materials is based at least in part on forming the second conductive material in the plurality of second cavities, the second conductive material at the target layer of the stack of materials exposed via the first hole based at least in part on removing the second material from the target layer of the stack of materials.

21. The method of claim 12, further comprising:
forming a second sacrificial material within the plurality of holes;
removing the second sacrificial material from a subset of the plurality of holes, the subset of the plurality of holes excluding the first hole;
forming a memory material in the subset of the plurality of holes based at least in part on removing the second sacrificial material, wherein the memory material is in contact with the conductive material at the target layer of the stack of materials based at least in part on forming the conductive material; and
removing the second sacrificial material from the first hole based at least in part on forming the memory material, wherein removing the portion of the sacrificial material via the first hole is based at least in part on removing the second sacrificial material from the first hole.

22. The method of claim 12, wherein the first dielectric material and the second dielectric material comprise an oxide material.

23. The method of claim 12, wherein the sacrificial material comprises a nitride material.

24. The method of claim 12, wherein the first material comprises a polysilicon material and the second material comprises a Boron-doped polysilicon material or a polysilicon material subjected to a silicidation process.

25. The method of claim 12, wherein the conductive material comprises a tungsten material, a molybdenum material, or a titanium alloy material, or a combination thereof.

26. A memory device, comprising:
a first layer comprising a plurality of string driver regions, wherein each string driver region extends in a first direction and is separated from other string driver regions of the plurality of string driver regions in a second direction, and wherein each string driver region of the plurality of string driver regions comprises a respective one or more string drivers and a respective one or more contacts; and
a plurality of array layers positioned above the first layer, the plurality of array layers comprising a plurality of contact regions and a plurality of array regions, wherein each contact region of the plurality of contact regions is positioned above a respective string driver region and comprises:
a conductive contact that extends in a third direction from the respective one or more contacts in the first layer through the plurality of array layers, wherein the conductive contact comprises conductive material that extends in the second direction in a target array layer of the plurality of array layers, and wherein the conductive contact is coupled with a first word line in a first array region of the plurality of array regions at the target array layer based at least in part on the conductive material extending in the second direction in the target array layer; and
wherein each array region of the plurality of array regions is positioned between a respective pair of contact regions in the second direction and comprises:
a plurality of bit lines that extend in the first direction in each second layer of the plurality of array layers, the plurality of bit lines positioned above the plurality of string driver regions in the first layer; and
one or more word lines that extend in the second direction in each array layer of the plurality of array layers.

27. The memory device of claim 26, further comprising:
a substrate, wherein the first layer is positioned above the substrate.

28. The memory device of claim 26, wherein each array region of the plurality of array regions further comprises:
a plurality of memory cells stacked in the third direction, wherein the one or more word lines are coupled with the plurality of memory cells.

29. The memory device of claim 28, wherein the target array layer comprises at least one memory cell of the plurality of memory cells that is coupled with the conductive contact via at least one word line of the one or more word lines.
